(19) United States
(12) Patent Application Publication
(10) Pub. No.: US 2006/0076677 A1
(43) Pub. Date: Apr. 13, 2006

(54) Resist sidewall spacer for C4 BLM undercut control

(75) Inventors: Timothy Harrison Daubenspeck, Colchester, VT (US); Jeffrey Peter Gambino, Westford, VT (US); Christopher David Muzzy, Burlington, VT (US); Wolfgang Sauter, Richmond, VT (US)

Correspondence Address: George R. McGuire;Bond, Schoeneck & King, PLLC, One Lincoln Center, Syracuse, NY, 13202, US

(73) Assignee: International Business Machines Corporation, Armonk, NY (US)

(21) Appl. No.: 10/964,495

(22) Filed: Oct. 12, 2004

(51) Int. Cl. H01L 23/48

(52) U.S. Cl. 257/734

(57) ABSTRACT

A method and system for preventing undercutting of the solder bump in a C4 package by forming a barrier of resist that effectively widens the footprint of the solder bump. The BLM is then etched to the perimeter edge of the barrier rather than the solder bump, thereby precluding any undercutting of the solder bump by the BLM. The barrier may formed by using a half-tone mask that fully exposes the immediately surrounding regions to define a sidewall enclosing the C4 cavity. The barrier may also be formed by applying a second resist prior to, or after, plating the solder and then patterning to inhibit etching directly adjacent to the C4 cavity. The barrier may additionally be formed by overfilling solder into the C4 cavity so that it spreads laterally over the sidewall portion of the resist layer. The resist is then etched anisotropically to leave the barrier. In another embodiment, a taper is introduced into the profile of the C4 cavity by reflowing the resist by an annealing step. The resist is then etched anisotropically to leave the barrier surrounding the C4 solder.

### BACKGROUND OF THE INVENTION

1. Field of Invention

The present invention relates to the manufacture of integrated chips and, more specifically, to a system and method for preventing undercut of bump limiting metallurgy (BLM) during controlled collapse chip connection (C4) manufacturing.

2. Description of Prior Art

C4 is a system for connecting a chip to a carrier that allows for a high density of input/output (I/O) terminals. During the C4 technique, a silicon wafer and associated metal pad are passivated and etched to form a cavity containing an exposed contact point at the metal pad. A number of layers of metal alloys or metal compounds are then deposited over the passivated chip and exposed metal pad to form the BLM. The BLM controls the expansion of solder bumps during reflow and serves as an adhesive and diffusion barrier layer. Solder is subsequently deposited in each cavity over the BLM and allowed to reflow to form contact bumps. Excess BLM between adjacent solder bumps is then removed by conventional wet etching techniques.

The wet etching process often results in one or more of the BLM layers undercutting the solder bump. For example, the underlying layers may be etched so that their perimeter edges undercut the solder bump or an overlying layer. When the pitch and size of C4 bumps decrease, undercutting compromises the reliability of the package. Conventional methods for preventing over-etching and the resulting undercutting include the deposition of an additional photoresist layer around the perimeter of the solder bump and the use of an additional wet etch step. This processing requires additional steps, however, and does not protect all BLM layers from undercutting.

3. Objects and Advantages

It is a principal object and advantage of the present invention to provide a method for preventing undercutting of all BLM layers during wet etch processing.

It is an additional object and advantage of the present invention to provide a method for preventing undercutting of BLM layers that does not require additional processing steps.

It is a further object and advantage of the present invention to provide a method for preventing undercutting of BLM layers that may be performed concurrently with convention processing.

Other objects and advantages of the present invention will in part be obvious, and in part appear hereinafter.

### SUMMARY OF THE INVENTION

In accordance with the foregoing objects and advantages, the present invention includes a method of preventing undercutting of BLM layers after conventional processing to form a packaging including a chip, exposed metal pad, and BLM layers. The preferred method of preventing undercutting comprises the use of a modified mask to image a thick resist layer applied over the BLM layers. The mask defines a region encircling the intended location of the C4 column, so that after developing and controlled anisotropic etching, a barrier is left which surrounds the plated C4 column. The barrier prevents undercutting from approaching dimensions which cause failures by effectively widening the footprint of the solder bump during the wet etching process.

A first embodiment of the present invention comprises the application of a negative resist layer over a conventionally prepared BLM layer. Instead of patterning the resist layer to define the C4 cavities, a half-tone mask (semitransparent MoSi-on-glass mask or pixilated chrome-on-glass mask) is used which does not expose the C4 cavity area, fully exposes the immediately surrounding regions to define a sidewall enclosing the C4 cavity regions, and only partially exposes the outer field regions. The resist layer is then developed to form the C4 cavities (i.e., regions with no exposure), sidewalls (i.e., in regions with full exposure), and partially etched perimeter (i.e., in regions with partial exposure). A nickel barrier is deposited in the C4 cavities and the solder is plated. The resist is then etched to leave a sidewall adjacent the C4 solder and complete remove the resist in the field regions. The BLM layers are then wet etched to the outer edges of the sidewalls, thereby preventing the undercutting of the solder by the etched BLM. The resist is then stripped and the solder is annealed to form the solder bumps.

In a second embodiment of the present invention, a conventional BLM layer is deposited and a patterned resist layer with a C4 cavity is formed with a nickel barrier deposited therein. A second resist pattern is then applied and patterned to inhibit etching directly adjacent to the C4 cavities and solder is deposited into the C4 cavity. Subsequent etching removes all of the resist in the field regions but resist sidewalls remain around the C4 cavity. Solder is plated and the BLM layers are wet etched, with the sidewalls preventing undercutting of the solder bump. The resist is then stripped and the solder is annealed to form the solder bumps.

In a third embodiment of the present invention, a conventional BLM layer is deposited, and a patterned resist layer with a C4 cavity is formed, with a nickel barrier deposited therein. Solder is plated into the cavity. A second resist layer is applied and patterned to inhibit etching of sidewalls directly adjacent to the C4 solder bump. The resist is etched to leave the protective sidewalls and all resist is removed from the field regions. The BLM layers are then wet etched and the sidewalls prevent undercutting of the solder. The resist is then stripped and the solder is annealed to form the solder bumps.

In a fourth embodiment of the present invention, a conventional BLM layer is deposited, and a patterned resist layer with a C4 cavity is formed, with a nickel barrier deposited therein. Solder is then overfilled into the C4 cavity and allowed to spread laterally over a portion of the resist layer. The resist is then etched anisotropically to leave a sidewall surrounding the solder while removing the resist from the field regions. The anisotropic etch of resist is achieved using oxygen-based reactive ion etching (RIE). The BLM layers are then wet etched and the sidewalls prevent undercutting of the solder. The resist is then stripped and the solder is annealed to form the solder bumps.

In a fifth embodiment of the present invention, a conventional BLM layer is deposited, and a patterned resist layer with a C4 cavity is formed. A taper is introduced into the profile of the C4 cavity by reflowing the resist by an annealing step. After annealing, the nickel barrier and solder are deposited into the C4 cavity. The resist is then etched anisotropically, leaving a sidewall adjacent the C4 solder while completely removing resist in the field regions. The BLM layers are wet etched, the resist is stripped, and the solder is annealed to form the solder bump.

### BRIEF DESCRIPTION OF THE DRAWINGS

The present invention will be more fully understood and appreciated by reading the following Detailed Description in conjunction with the accompanying drawings, in which:

FIG. 1 is a cross-sectional schematic of a portion of a C4 package including multiple layers of BLM.

FIG. 2 is a cross-sectional schematic of a semiconductor package exhibiting undercutting of solder bump by the BLM.

FIG. 3-5 are cross-sectional schematics of a passivated semiconductor wafer and bonding pad including a multi-layered BLM.

FIG. 6 is a cross-sectional schematic a passivated semiconductor wafer, bonding pad, and multi-layer BLM structure having a later of resist thereon.

FIGS. 7-10 are cross-sectional schematics of conventional C4 manufacturing stages.

FIGS. 11-14 are cross-sectional schematics of the stages of a first embodiment of the present invention.

FIG. 15-17 are cross-sectional schematics of a stage of a second embodiment of the present invention.

FIG. 18-20 are cross-sectional schematics of stages of various embodiments of the present invention.

FIG. 21 is a cross-sectional schematic of a stage of a third embodiment of the present invention.

FIG. 22 is a cross-sectional schematic of a stage of a fourth embodiment of the present invention.

FIG. 23 is a cross-sectional schematic of a stage of a fifth embodiment of the present invention.

### DETAILED DESCRIPTION

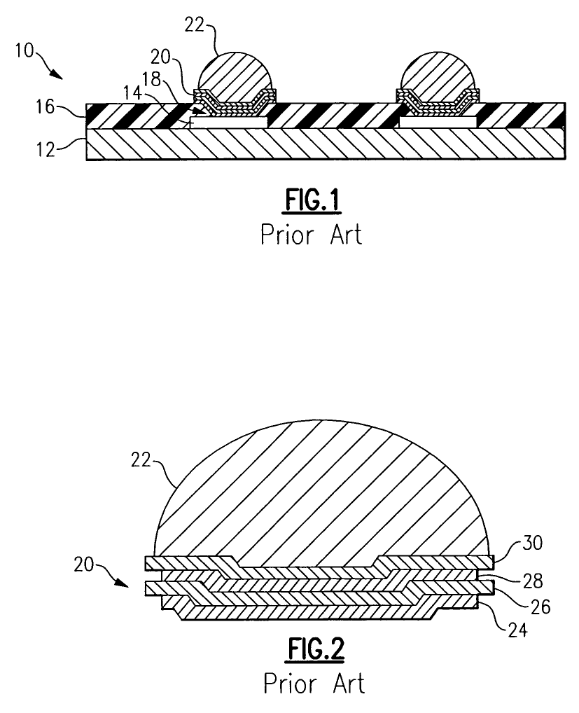

Referring now to the drawings, wherein like numeral refer to like parts throughout, there is seen in FIG. 1 a conventional semiconductor device 10 comprising a wafer or substrate 12 and a bonding pad 14. Substrate 12 may comprise silicon, gallenium arsenide or other known semiconducting materials and bonding pad 14 may be formed from copper, aluminum, or similar metallic compounds. Device further comprises a passivation layer 16 of a polyimide or silicon dioxide layered over substrate 12. Other materials include an insulating polymer, oxide, nitride (SiN, SiON), silicon nitride, or carbide dielectrics (SiC, SiCN, SiCO, etc.). Passivation layer 16 includes at least one terminal via 18 formed therethrough to expose bonding pad 14.

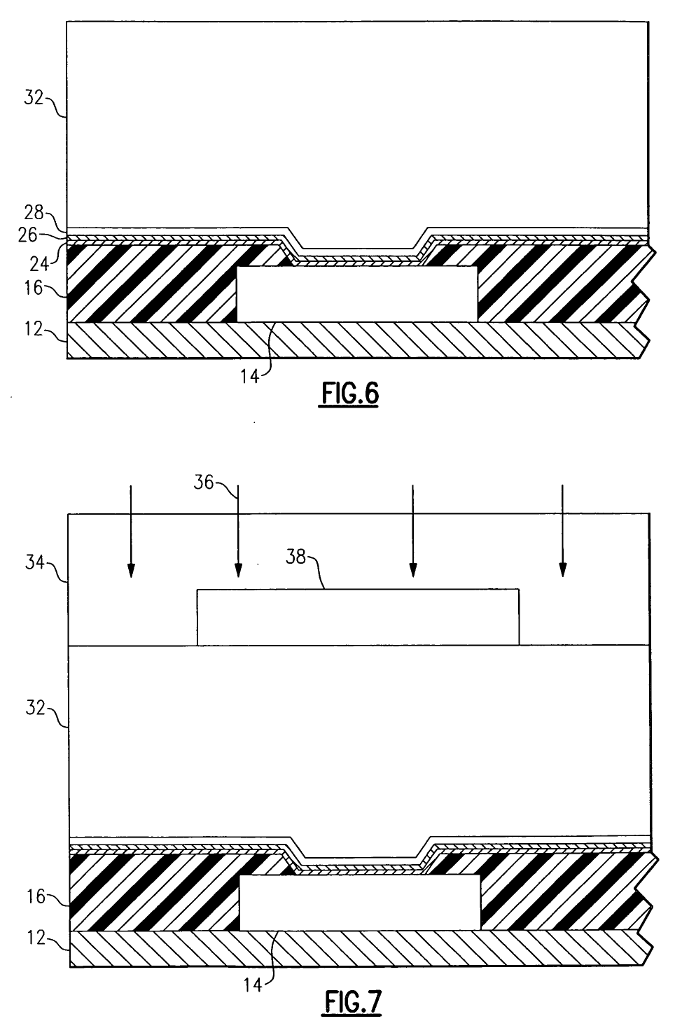

Device 10 further includes a ball limiting metallurgy (BLM) structure 20 sequentially deposited over the passivation layer 18 and in via 18. As seen in FIGS. 3-5, BLM structure 20 comprises multiple layers of metals and/or metal compounds sequentially deposited by evaporation over passivation layer 12 and via 18. The layers of BLM structure 20 may comprise titanium tungsten (TiW), chromium copper (CrCu), copper (Cu), and nickel sulfur (NiS) that are sequentially deposited through a mask and wet etched to remove excess BLM alloys between adjacent bumps 22. Other materials may include Au, Ti, TiN, W, Ta, TaN, TaSiN, WCN, and the like which provide adhesion, diffusion and electrochemical migration protection. BLM structure 20 improves adhesion of subsequently deposited solder bumps 22 that electrically interconnect bonding pad 14 and substrate 12 to a printed circuit board or other device.

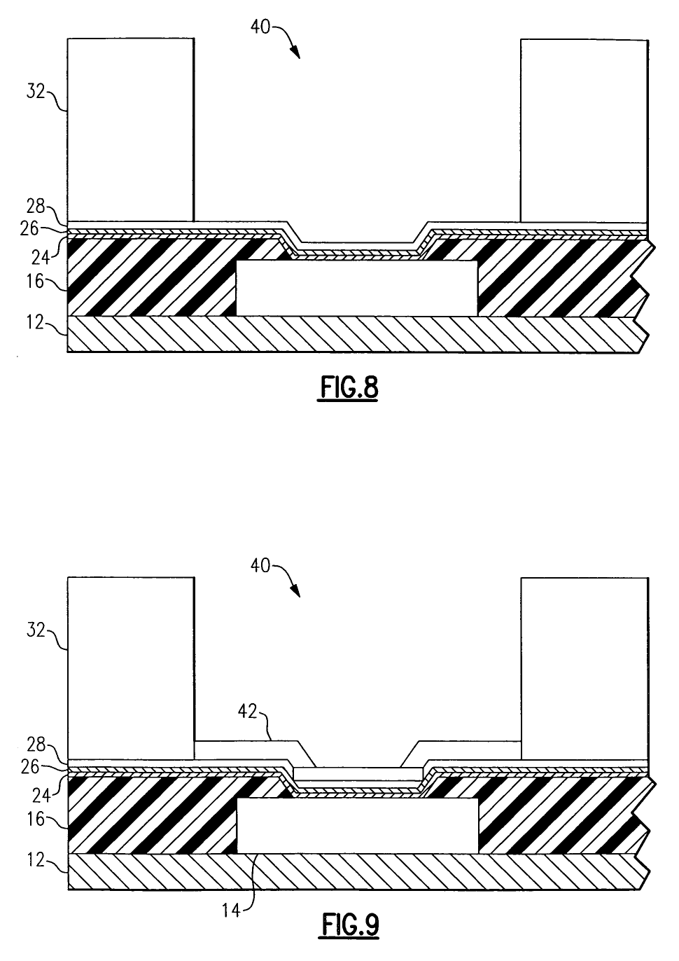

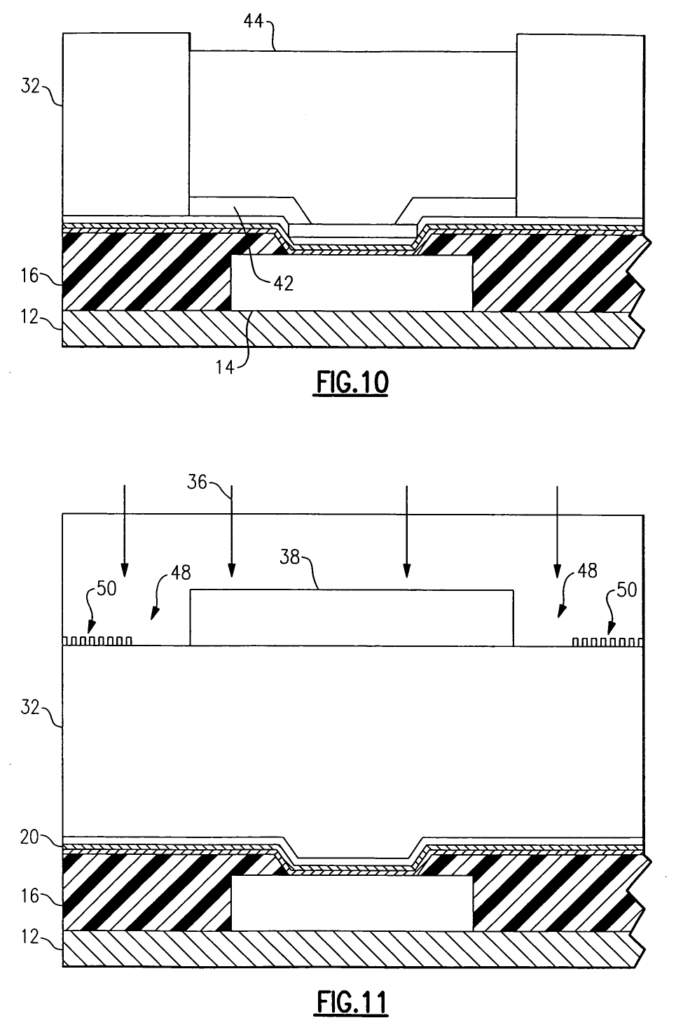

As seen in FIGS. 6-10, solder bumps 22 are formed by first applying a thick layer of resist material 32 over BLM structure 20. A mask 34 having variable transmissivity is then used to control the exposure of resist 32 when light 36 is applied during a lithography process. Mask 34 contains a non-transmissive region 38 in alignment with bonding pads 14 and vias 18. The non-exposed resist 32 in region 38 is then removed by an aqueous resist developer to form bump cavities 40, such oxygen ash. A nickel barrier 42 is deposited in cavity 40 and C4 solder 44 is plated into cavity 40. Excess BLM 20 is then wet etched and the remaining resist 32 is then stripped away. For example, TiW is etched with an H₂O₂-based wet etch, Cu and CrCu are etched with a sulfur-based wet etch.

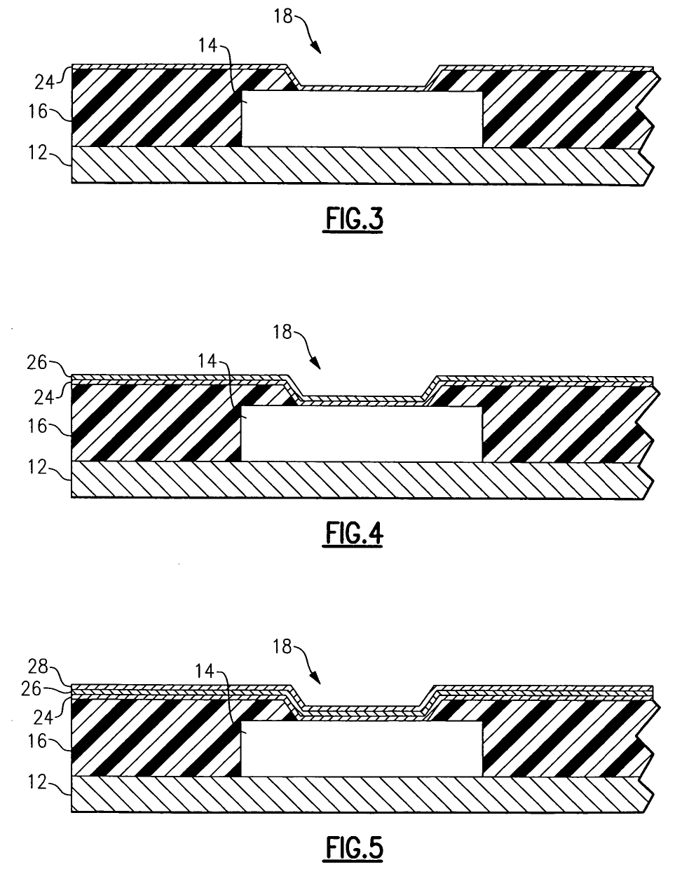

Referring to FIG. 2, the various metal layers of BLM structure 22 may be etched at different rates, thereby leading to undercutting of bump 22 or adjacent layers. If BLM structure comprises layers of TiW 24, CrCu 26, Cu 28, and NiS 30, the TiW 24 and Cu 28 are subject to over-etching and may undercut CrCu layer 26 and NiS layer 30, thereby degrading the integrity of the adhesion with bump 22.

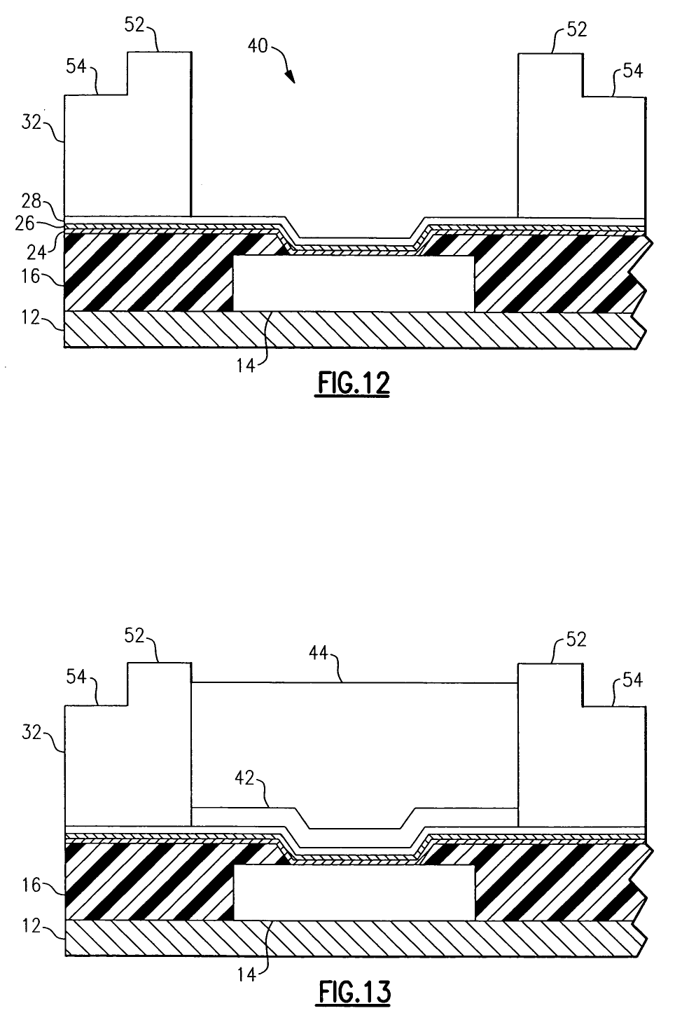

As seen in FIG. 11, the first embodiment of the present invention departs from conventional processing after the thick layer of resist 32 has been applied over BLM structure 22, as seen in FIG. 6. Instead of using conventional mask 34, a half-tone mask 46 that, in addition to having a non-transmissive region 38 in alignment with bonding pads 14 and vias 18, includes a fully transmissive region 48 surrounding non-transmissive region 38 and a partially transmissive region 50 surrounding fully transmissive region 48. After exposure to light 36 and developer, the negative resist 32 is completely removed in areas in alignment with the non-transmissive region 38, and resist 32 is partially removed in the areas in alignment with the partially transmissive region 50.

As seen in FIG. 12, etching after exposure using half-tone mask 46 leaves protective sidewalls 52 surrounding bump cavity 40. Non-transmissive region 38 of half-tone mask 46 should be dimensioned to leave sidewalls 52 having a width of approximately 1 μm to 20 μm. Partially transmissive region 50 creates partially etched field regions 54. Mask 46 preferably comprises molybdenum silicon on glass or chrome-on-glass.

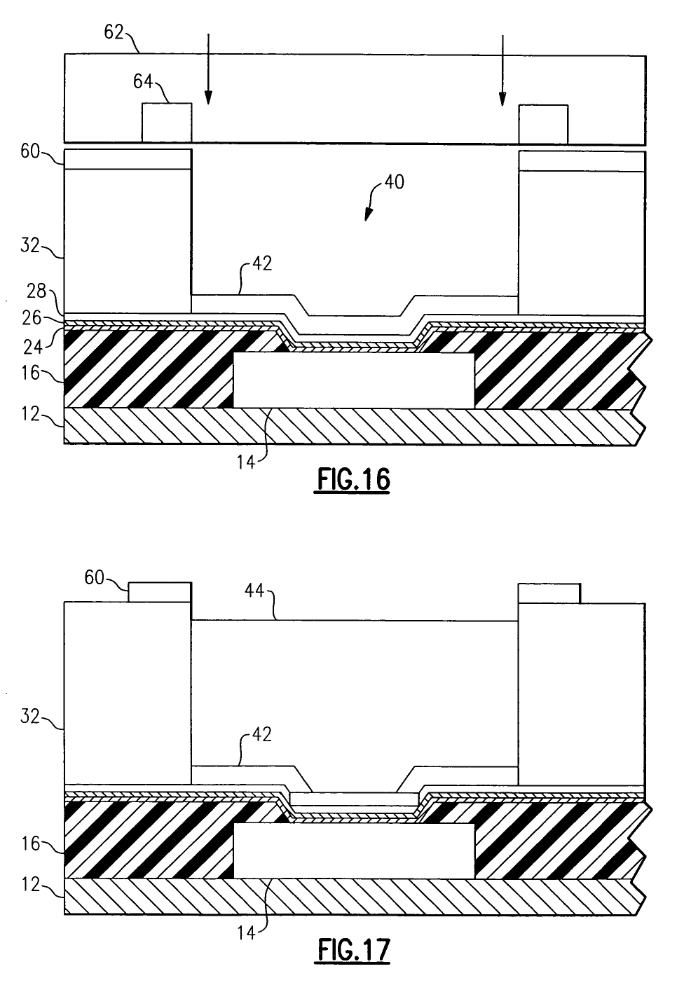

After etching of resist 32 to form sidewalls 52 and field regions 54, nickel barrier 42 may be deposited into cavity 40. Nickel barrier 42 is preferably 400 μm thick. Solder 44 is then plated into cavity 40 to an approximate thickness of 100 μm. Remaining resist 32 in sidewalls 52 and field regions 54 are then etched to leave a sidewall barrier 56 of approximately 1 μm to 20 μm in width adjacent to solder 44 and nickel barrier 42. As seen in FIGS. 18-19, barriers 56 prevent undercutting of solder 44 when BLM structure 20 is etched. After etching of BLM structure 20, barrier 56 is stripped away and solder 44 is annealed to form bumps 22 as seen in FIG. 20.

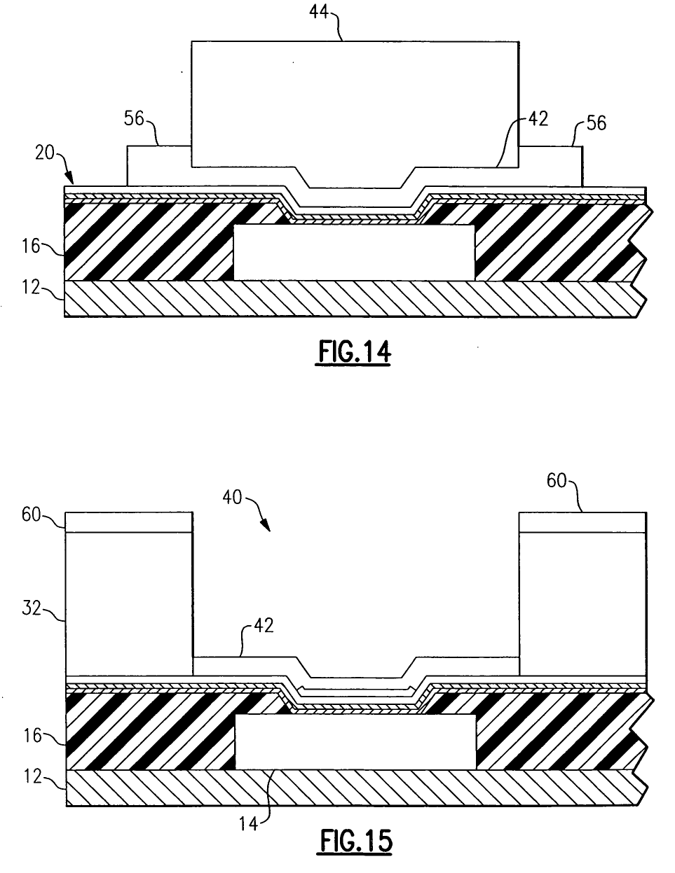

Referring to FIG. 15, a second embodiment of the present invention comprises the conventional preparation of device 10 to include a first resist layer 32 that is masked and etched to form a cavity 40, as shown in FIGS. 6-8. Nickel barrier 42 is deposited in cavity 40 and a second resist 60 is applied over first resist 32. A mask 62 that has non-transmissive regions 64 in alignment with first resist 32 surrounding and adjacent to cavity 40 is used to expose second resist 60. After etching second resist 60, solder 44 is deposited into cavity 40. Subsequent etching removes all first resist 32 in field regions 54, leaving barriers 56 surrounding solder 44 and nickel 42. As seen in FIGS. 18-19, barriers 56 prevent undercutting of solder 44 when BLM structure 20 is etched. As seen in FIG. 20, all resist 32 is removed and solder 44 is annealed to form solder bump 22.

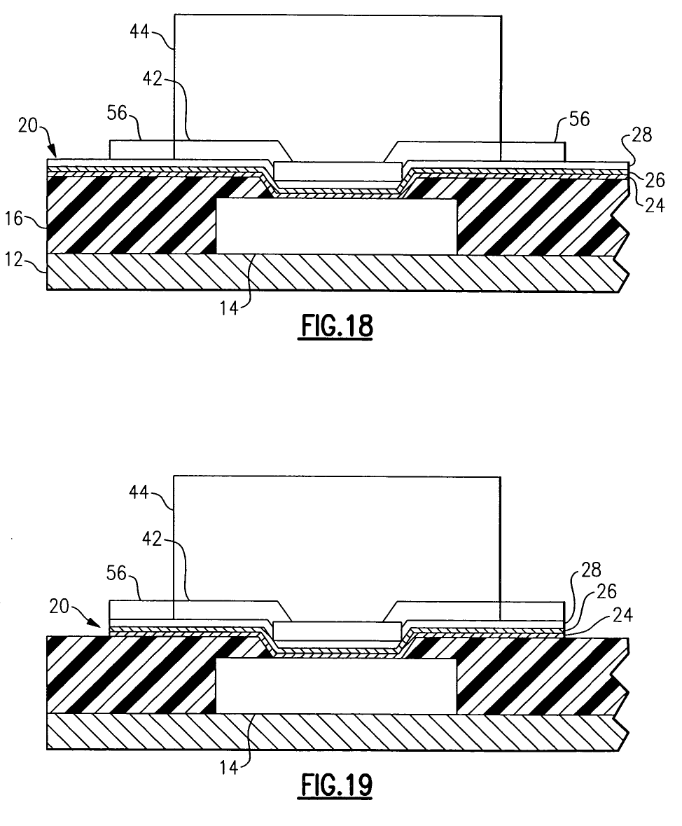

Referring to FIG. 21, a third embodiment of the present invention comprises a conventional formation of device 10 including a first resist layer 32 and a C4 cavity 40 formed therein. A nickel barrier 42 is deposited in cavity 40 and solder 44 is plated into cavity 40 over nickel 42. A second resist 66 is then applied over first resist layer 32 and solder 44. Second resist 66 is patterned by a mask 66 containing a non-transmissive region 68 that is in alignment with solder 44 and extends outwardly to include an extended perimeter portion 70 for inhibiting etching of resist 32 in sidewalls 54 directly surrounding solder 44. After etching, protective barrier 56 surrounding solder 44 is left. As explained above, barrier 56 prevents undercutting of solder 44 when BLM structure 20 is wet etched. All resist 32 is removed and solder 44 is annealed to form solder bump 22, as seen in FIG. 20.

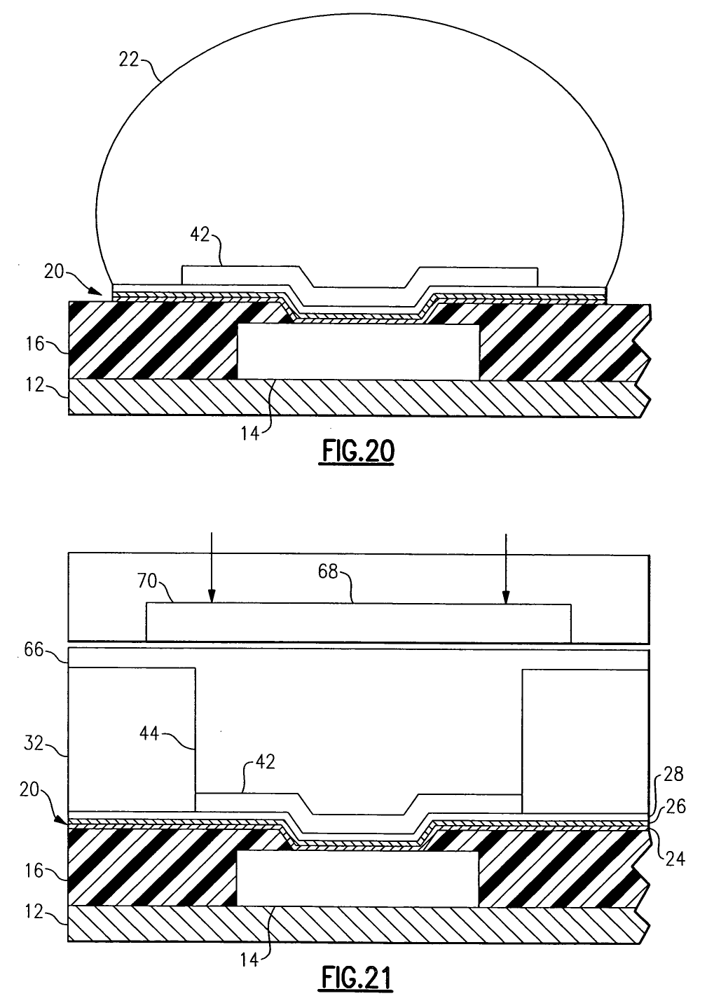

Referring to FIG. 22, a fourth embodiment of the present invention comprises the conventional formation of a device 10 including a resist layer 32 and a cavity 40 formed therein. A nickel barrier 42 is deposited in cavity 40 and solder 44 is overfilled into cavity 40 so that it spreads laterally over surrounding sidewalls 52 by increasing the deposition time in the plating tool. Resist 32 is then etched anisotropically to remove all resist 32 in field regions 54, leaving a barrier 56 surrounding solder 44. BLM structure 20 is then wet etched and barrier 56 prevents undercutting of solder 44. All resist 32 is removed and solder 44 is annealed to form solder bump 22, as seen in FIG. 20.

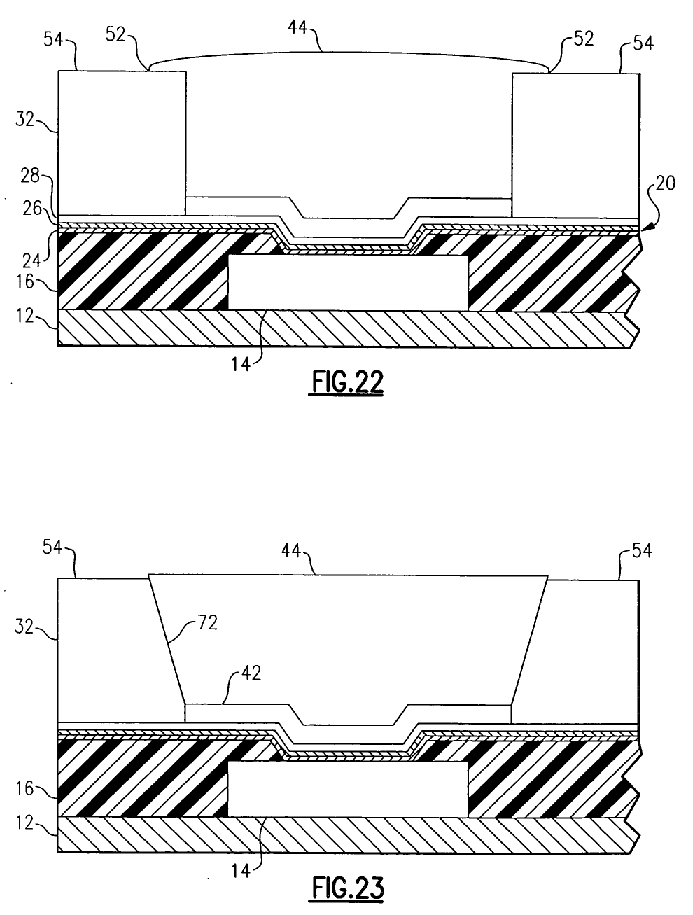

Referring to FIG. 23, a fifth embodiment of the present invention comprises the conventional formation of a device 10 including a resist layer 32 and a cavity 40 formed therein. A taper 72 in sidewalls 54 toward pad 14 is introduced by reflowing resist 32 through an annealing step of about 100 to 120 degrees Celsius for approximately 1 to 10 minutes. After annealing, a nickel barrier 42 and solder 44 are deposited into cavity 40. Resist 32 is then etched anisotropically, leaving a barrier 56 surrounding solder 44. As explained above, barrier 56 prevents undercutting of solder 44 when BLM structure 20 is wet etched. All resist 32 is removed and solder 44 is annealed to form solder bump 22, as seen in FIG. 20.

What is claimed is:

1. A mask for patterning a layer of resist applied to a passivated wafer prior to etching, said mask comprising:
a first region precluding full transmittance for defining a solder cavity in said resist when etched;
a second region allowing full transmittance surrounding said first region for defining a barrier of said resist around said cavity when etched; and
a third region of partial transmittance surrounding said second region for defining a field region in said resist when etched.

2. The mask of claim 2, wherein said mask comprises molybdenum-silicon on glass.

3. The mask of claim 2, wherein said mask comprises chrome-on-glass.

4. A semiconducting device, comprising:
a passivated substrate including a terminal via formed therein to expose a bonding pad;
at least one layer of bump limiting metallurgy deposited over said substrate and said terminal via;
a layer of nickel deposited in said terminal via;
solder plated in said terminal via over said nickel; and
a barrier of resist surrounding said solder, said nickel, and covering said bump limiting metallurgy immediately adjacent to said solder and said nickel.

5. The device of claim 4, wherein said layer of nickel is about 400 μm in thickness.

6. The device of claim 4, wherein said solder is about 100 μm in thickness.

7. The device of claim 4, wherein said barrier is between about 1 μm to about 20 μm in width.

8. The device of claim 4, wherein said bump limiting metallurgy comprises a layer of titanium tungsten alloy, a layer of chromium copper alloy, a layer of copper, and a layer nickel tin alloy.

9. A method of forming a C4 solder member on a semiconducting device including a substrate, a bonding pad, and a passivation layer having a via formed therethrough, said method comprising the steps of:
depositing at least one layer of bump limiting metallurgy over said passivation layer;
applying a layer of resist over said at least one layer of bump limiting metallurgy;
masking said resist to allow etching in at least a first region of said resist;
etching to remove all of said resist from said first region to define a cavity having sidewalls of said resist;
plating solder into said cavity;
wet etching said at least one layer of bump limiting metallurgy; and
stripping said resist away.

10. The method of claim 9, wherein the step of masking to preclude exposure of at least a first region of said resist further includes fully exposing said resist in at least a second region surrounding said first region, and partially exposing said resist in at least a third region surrounding said second region.

11. The method of claim 10, wherein the step of etching said resist to remove all of said resist from said first region to define a cavity having sidewall of said resist further comprises not etching resist from said second region, and only partially etching said resist from said third region, thereby defining a cavity in said first region, leaving sidewalls of said resist surrounding said cavity, and forming partially etched field region surrounding said sidewalls.

12. The method of claim 11, wherein the step of wet etching said at least one layer of bump limiting metallurgy comprises etching said at least one layer of bump limiting metallurgy until aligned with the outer perimeter of said barrier.

13. The method of claim 12, further comprising the step of depositing a nickel barrier in said cavity prior to plating said solder.

14. The method of claim 9, further comprising the steps of:
applying a second layer of resist over said first layer of resist after said first layer of resist has been etched to define said cavity;
masking said second layer of resist to preclude etching in a second region surrounding said cavity; and
etching said second layer of resist and said first layer of resist, thereby leaving a barrier surrounding said cavity after the step of plating solder in said cavity.

15. The method of claim 14, wherein the step of applying a second layer of resist is performed before the step of plating said solder into said cavity.

16. The method of claim 15, wherein the step of applying a second layer of resist is performed after the step of plating said solder into said cavity.

17. The method of claim 9, wherein the step of plating solder into said cavity comprises overfilling solder in said cavity to cover a second region of said resist surrounding said cavity.

18. The method of claim 17, further comprising the step of anisotropically etching said resist to leave a barrier of resist in said second region that surrounds said cavity.

19. The method of claim 9, further comprising the steps of:
annealing to reflow said resist to form a taper in said sidewalls of said cavity; and
anisotropically etching said resist to leave a barrier of resist surrounding said cavity.
